(19) United States
(12) Patent Application Publication
(10) Pub. No.: US 2014/0010547 A1
(43) Pub. Date: Jan. 9, 2014

(54) ACTIVE OPTICAL ANTENNA, MICROWAVE TRANSMITTING SYSTEM AND INFORMATION SENDING METHOD

(71) Applicant: Huawei Technologies Co., Ltd., Shenzhen (CN)

(72) Inventors: Limin Dong, Shenzhen (CN); Kun Li, Chengdu (CN); Jun Cai, Chengdu (CN)

(73) Assignee: Huawei Technologies Co., Ltd., Shenzhen (CN)

(21) Appl. No.: 14/012,742

(22) Filed: Aug. 28, 2013

Related U.S. Application Data
(63) Continuation of application No. PCT/CN2012/072250, filed on Mar. 13, 2012.

(30) Foreign Application Priority Data
Mar. 25, 2011 (CN) 201110074033.7

(51) Int. Cl. H04B 10/27; H03K 17/78; H04B 1/04

(52) U.S. Cl. CPC H04B 10/271; H04B 1/0483; H03K 17/78
USPC 398/116; 250/208.2

(57) ABSTRACT

Embodiments of the present disclosure disclose an active optical antenna, a microwave transmitting system and an information sending method. The active optical antenna includes: a substrate; a ground disposed at the bottom of the substrate; a power supply grid and several antenna units that are disposed at the top of the substrate, and photodetector tubes that are disposed in the substrate and located between the antenna units and the ground, where the power supply grid supplies power to the photodetector tubes, the number of the photodetector tubes is equal to the number of the antenna units, and output ends of the photodetector tubes are coupled with the antenna units to output radio frequency signals; and optical waveguides which are disposed in the substrate and connected to the photodetector tubes.

### CROSS-REFERENCE TO RELATED APPLICATIONS

This application is a continuation of International Application No. PCT/CN2012/072250, filed on Mar. 13, 2012, which claims priority to Chinese Patent Application No. 201110074033.7, filed on Mar. 25, 2011, both of which are hereby incorporated by reference in their entireties.

### FIELD

The present disclosure relates to a communication system, and in particular to an active optical antenna, a microwave transmitting system and an information sending method.

### BACKGROUND

Serving as a conventional communication manner, a microwave used to play an important role in the communications field. The microwave has inherent advantages such as simple deployment, low cost, and relatively far transport distance. With the continuous development of a communication network, the microwave still has a very wide application range, especially in the backhaul of a mobile base station and in a remote area with a complex terrain, where the microwave is giving play to its advantages and is widely applied. As transmit data traffic keeps growing, a conventional microwave frequency band is more and more crowded. To improve the transport bandwidth of the microwave, a new spectrum frequency band: 71-76 GHZ/81-86 GHZ, an E-band microwave (E-BAND), is found in the industry. The available bandwidth of this frequency band reaches 10 GHZ, which can meet a transport need of a high speed data service (such as GE/10 GE).

An existing method for implementing modulation of an intermediate frequency signal by using an optical modulator and thereby transmitting the signal is as shown in FIG. 1. In this embodiment, in a modulator (MD, Modulator), after local (LO, local) modulation is performed on a local modulation signal whose frequency is f/2, a laser (LD, laser diode) generates an optical carrier whose frequency difference is f. After modulation is performed by the modulator MD, where data is modulated onto the optical carrier, the optical carrier whose frequency difference is f forms a difference frequency optical signal, and then the difference frequency optical signal enters a photodetector (PD, Photodetector) tube, beat frequency is performed and a radio frequency signal is generated. The radio frequency signal is amplified by an amplifier and then is transmitted through an antenna. Generally, conversion output power of the PD tube is relatively low, and that the radio frequency signal obtained by the conversion performed by the PD tube directly enters the antenna often cannot meet a requirement of transmit power. Therefore, an amplifier needs to be added. However, an integration level of an antenna system is reduced and the costs of the antenna system are increased for every additional device.

### SUMMARY

An objective of embodiments of the present disclosure is to provide an active optical antenna, a microwave transmitting system and an information sending method to reduce the costs of the antenna and increase an integration level of the antenna.

An embodiment of the present disclosure provides an active optical antenna, including: a substrate; a ground disposed at the bottom of the substrate; a power supply grid and several antenna units that are disposed at the top of the substrate, and photodetector tubes that are disposed in the substrate and located between the antenna units and the ground, where the power supply grid supplies power to the photodetector tubes, the number of the photodetector tubes is equal to the number of the antenna units, and output ends of the photodetector tubes are coupled with the antenna units to output radio frequency signals; and optical waveguides which are disposed in the substrate and connected to the photodetector tubes.

An embodiment of the present disclosure further provides a microwave transmitting system, including: a server configured to generate optical difference frequency signals to be transmitted, adjust the optical difference frequency signals to make them on an optical carrier, and transmit the signals to an active optical antenna through an optical fiber; and the active optical antenna, configured to: through optical waveguides in a substrate of the active optical antenna, distribute optical signals received through the optical fiber to multiple photodetector tubes, where the multiple photodetector tubes convert the received optical difference frequency signals to radio frequency signals, and the radio frequency signals are sent out through antenna units.

An embodiment of the present disclosure further provides an information sending method, including: powering on an active optical antenna; receiving optical signals to be transmitted, and distributing the optical signals to multiple photodetector tubes through optical waveguides in a substrate of the active optical antenna; and converting, by the multiple photodetector tubes, the received optical signals to radio frequency signals, and sending out the radio frequency signals through antenna units.

By applying the embodiments of the present disclosure, the optical difference frequency signals are converted to the radio frequency signals by the PD tubes, and the radio frequency signals are sent out through the antenna units coupled with the PD tubes. A PD tube is an active device, which may reach an mw level per unit, and integration of multiple PD tubes avoids a problem that power of a single PD tube is too low. In this way, use of an amplifier is avoided by the integration of the multiple PD tubes, which reduces the cost of the antenna and increases the integration level of the antenna. Furthermore, the signals which are to be transmitted and received by the antenna are optical signals. Therefore, complex optical splitting may be completed by using a planar waveguide technology, so that optical power distribution is completed in an optical domain, which avoids matching and attenuation in an electrical signal distribution network.

In addition, it is convenient for phase control of the optical signals in the optical domain. Therefore, it may be simple and convenient to form an array of phased array antennas. The active optical antenna is connected to the central office through the optical fiber. Therefore, it is convenient for operations such as remote antenna deployment and construction.

### BRIEF DESCRIPTION OF THE DRAWINGS

To illustrate the solutions in the embodiments of the present disclosure and in the prior art more clearly, the following briefly introduces the accompanying drawings required for describing the embodiments and the prior art. Apparently, the accompanying drawings in the following description show merely some embodiments of the present disclosure, and a person of ordinary skill in the art may still derive other drawings from these accompanying drawings without marking creative efforts.

FIG. 1 is a schematic diagram of a signal transmitting manner in the prior art;

FIG. 2 is a schematic diagram of a main structure of an active optical antenna according to an embodiment of the present disclosure;

FIG. 3 is a schematic diagram of a sectional structure of the active optical antenna according to the embodiment of the present disclosure;

FIG. 4 is a schematic diagram of a top structure of the active optical antenna according to the embodiment of the present disclosure;

FIG. 5 is a schematic structural diagram of a microwave transmitting system according to an embodiment of the present disclosure; and FIG. 6 is a flow chart of an information sending method according to an embodiment of the present disclosure.

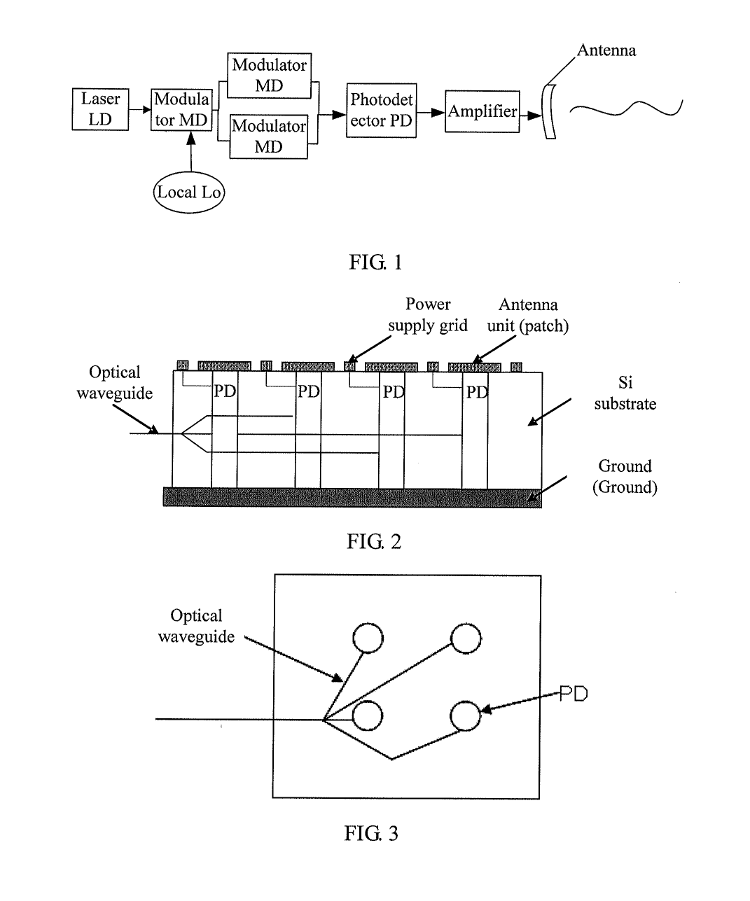

### DETAILED DESCRIPTION OF THE EMBODIMENTS

The following clearly describes the solutions in the embodiments of the present disclosure with reference to the accompanying drawings in the embodiments of the present disclosure. Apparently, the described embodiments are merely a part rather than all of the embodiments of the present disclosure. All other embodiments obtained by a person of ordinary skill in the art based on the embodiments of the present disclosure without making creative efforts shall fall within the protection scope of the present disclosure.

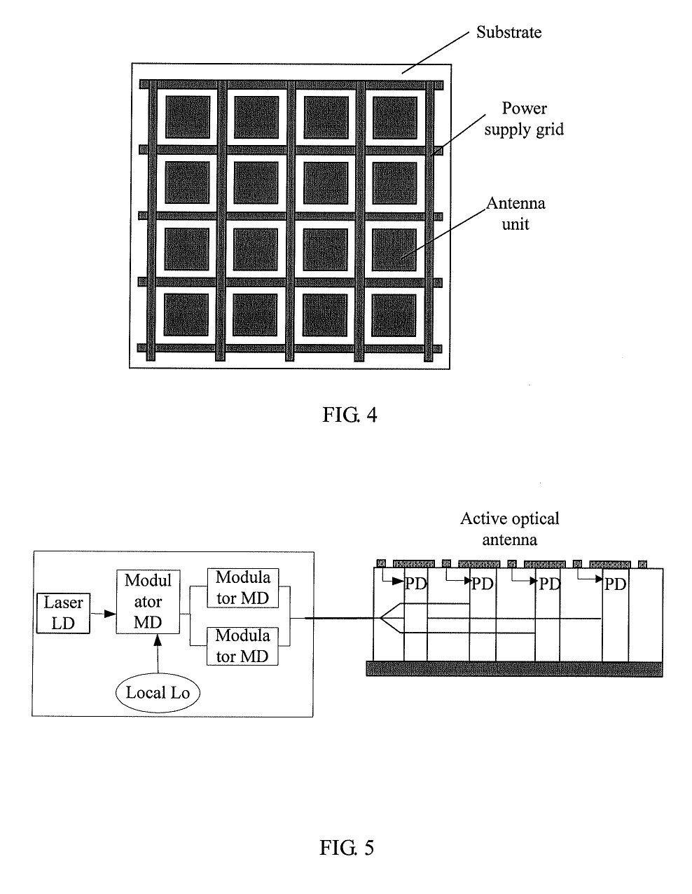

Referring to FIG. 2 to FIG. 4, FIG. 2 is a schematic diagram of a main structure of an active optical antenna according to an embodiment of the present disclosure, FIG. 3 is a schematic diagram of a sectional structure of the active optical antenna according to the embodiment of the present disclosure, and FIG. 4 is a schematic diagram of a top structure of the active optical antenna according to the embodiment of the present disclosure. It may be known in combination with the three drawings that, the active optical antenna provided in the embodiment of the present disclosure includes: a substrate; a ground (Ground) disposed at the bottom of the substrate; a power supply grid and several antenna units (Patch) that are disposed at the top of the substrate, and photodetector (PD) tubes that are disposed in the substrate and located between the antenna units and the ground, where the power supply grid supplies power to the photodetector tubes, output ends of the photodetector tubes are coupled with the antenna units, and the number of the photodetector tubes is equal to the number of the antenna units; and optical waveguides which are disposed in the substrate and connected to the photodetector tubes.

The several antenna units are arranged in an array, and the power supply grid is distributed in intervals between the antenna units.

Any semiconductive material that is suitable for making an optical device and meets a requirement of a dielectric constant of an antenna substrate, such as silicon (Si), and indium phosphide (InP), may be selected and used as a substrate. Generally, a relative dielectric constant of Si reaches 11, and the costs of Si are relatively low. The substrate in the embodiment of the present disclosure is Si.

It should be noted that, because multiple PD tubes are integrated in the Si substrate, each PD tube corresponds to one antenna unit, that is, each PD tube obtains power from the power supply grid and implements power conduction by connecting to the ground, and an output end of each PD tube is coupled with the antenna unit, so that a radio frequency signal that is output is sent out through the antenna unit. In this way, the PD tube converts an optical beat frequency signal to a radio frequency signal, and directly sends the radio frequency signal to the antenna unit for transmission. An array of PD tubes integrated in the Si substrate may adopt a microwave photonic method to implement the conversion of the optical signal to the radio frequency signal. A specific conversion method is completely the same as that in the prior art, which is not repeatedly described here. The array of the integrated PD tubes meets a requirement of transmit power for the radio frequency signal obtained by the conversion performed by the PD tube to directly enter the antenna.

It may be seen that the active optical antenna provided in the embodiment of the present disclosure is actually a flat-panel display active optical antenna. By applying the antenna provided in the embodiment of the present disclosure, optical difference frequency signals are converted to radio frequency signals by the PD tubes directly coupled with the antenna units, so that information to be transmitted is sent out. A PD tube is an active device, which may reach an mw level per unit, and integration of multiple PD tubes avoids a problem that the power of a single PD tube is too low. In this way, it is unnecessary to use an amplifier because the multiple PD tubes are integrated, which reduces the costs of the antenna and increases an integration level of the antenna. Furthermore, signals which are to be transmitted and received by the antenna are optical signals. Therefore, complex optical splitting may be completed by using a planar waveguide technology, so that optical power distribution is completed in an optical domain, which avoids matching and attenuation in an electrical signal distribution network.

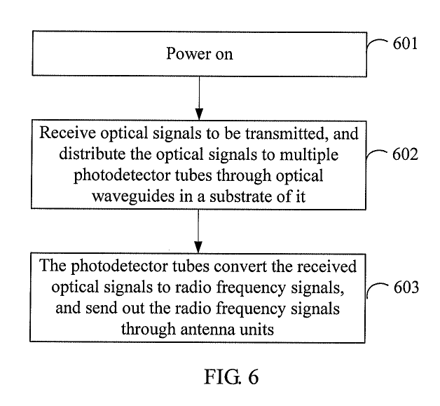

Referring to FIG. 5, a microwave transmitting system is provided according to an embodiment of the present disclosure. The the system specifically includes: a central office, configured to generate optical difference frequency signals to be transmitted, adjust the optical difference frequency signals to make them on an optical carrier, and transmit the signals to an active optical antenna through an optical fiber; and the active optical antenna, configured to: through optical waveguides in a substrate of the active optical antenna, distribute optical signals received through the optical fiber to multiple photodetector tubes, where the multiple photodetector tubes convert the received optical difference frequency signals to radio frequency signals, and the radio frequency signals are sent out through antenna units.

In this way, an array of integrated PD tubes meets a requirement of transmit power for the radio frequency signals obtained by the conversion performed by the PD tubes to directly enter the antenna.

After generating the optical difference frequency signals to be transmitted, the central office is further configured to perform phase adjustment and control on the optical difference frequency signals, so as to adjust a phase of the optical carrier that arrives at each photodetector tube in the active optical antenna, and then adjust the optical difference frequency signals that have undergone the adjustment and control to make them on the optical carrier. A specific phase adjustment and control method is the same as that in the prior art, which is not repeatedly described here.

The active optical antenna may be located at a remote end of the central office, and may also be close to the central office, which may be convenient for deploying the antenna according to an actual need.

By applying the microwave transmitting system provided in the embodiment of the present disclosure, optical difference frequency signals are converted to radio frequency signals by the PD tubes, and the radio frequency signals are sent out through the antenna units directly coupled with the PD tubes. A PD tube is an active device, which may reach an mw level per unit, and integration of multiple PD tubes avoids a problem that power of a single PD tube is too low. In this way, it is unnecessary to use an amplifier because the multiple PD tubes are integrated, which reduces the costs of the antenna and increases an integration level of the antenna. Furthermore, the signals which are to be transmitted and received by the antenna are optical signals. Therefore, complex optical splitting may be completed by using a planar waveguide technology, so that optical power distribution is completed in an optical domain, which avoids matching and attenuation in an electrical signal distribution network.

In addition, it is convenient for phase control of the optical signals in the optical domain. Therefore, it may be simple and convenient to form an array of phased array antennas. The active optical antenna is connected to the central office through the optical fiber. Therefore, it is convenient for operations such as remote antenna deployment and construction.

Referring to FIG. 6, it is a flow chart of an information sending method according to an embodiment of the present disclosure. The method is applied to the foregoing active optical antenna, and may specifically includes:

Step 601: Power on the active optical antenna.

Step 602: Receive optical signals to be transmitted, and distribute the optical signals to multiple photodetector tubes through optical waveguides in a substrate of the active optical antenna.

Step 603: The photodetector tubes convert the received optical signals to radio frequency signals, and send out the radio frequency signals through antenna units.

In this way, an array of integrated PD tubes meets a requirement of transmit power for the radio frequency signals obtained by the convesion performed by the PD tubes to directly enter the antenna.

The received optical signals to be transmitted may have not undergone phase adjustment and control, or may have undergone phase adjustment and control. A specific phase adjustment and control method is the same as that in the prior art, which is not repeatedly described here.

The antenna units are arranged in an array, and power is supplied to the active optical antenna through a power supply grid.

Any semiconductive material that is suitable for making an optical device and meets a requirement of a dielectric constant of an antenna substrate, such as silicon (Si), and indium phosphide (InP), may be selected and used as a substrate. Generally, a relative dielectric constant of Si reaches 11, and the costs of Si are relatively low. The substrate in the embodiment of the present disclosure is Si.

By applying the information transmitting method provided in the embodiment of the present disclosure, optical difference frequency signals are converted to radio frequency signals by the PD tubes in the active optical antenna, and the radio frequency signals are sent out through the antenna units directly coupled with the PD tubes. A PD tube is an active device, which may reach an mw level per unit, and integration of multiple PD tubes avoids a problem that power of a single PD tube is too low. In this way, it is unnecessary to use an amplifier because the multiple PD tubes are integrated, which reduces the costs of the antenna and increases an integration level of the antenna. Furthermore, the signals which are to be transmitted and received by the antenna are optical signals. Therefore, complex optical splitting may be completed by using a planar waveguide technology, so that optical power distribution is completed in an optical domain, which avoids matching and attenuation in an electrical signal distribution network.

In addition, it is convenient for phase control of the optical signals in the optical domain. Therefore, it may be simple and convenient to form an array of phased array antennas. The active optical antenna is connected to a central office through an optical fiber. Therefore, it is convenient for operations such as remote antenna deployment and construction.

It should be noted that in the foregoing embodiments, description of each embodiment has its emphasis. Reference may be made to relevant description of another embodiment for the part that is not described in detail in a certain embodiment.

It should be noted that in this application, the terminology “include,” “comprise,” or any other variant is intended to cover non-exclusive inclusion, so that a process, a method, an object or a device that includes a series of elements not only includes those elements, but also includes other elements that are not explicitly listed, or includes inherent elements of the process, method, object or device. In a case without further limitations, an element limited by the sentence “including one . . . ” does not exclude that another same element may also exist in the process, method, object, or device which includes the elements.

The foregoing descriptions are merely exemplary embodiments of the present disclosure, but are not intended to limit the protection scope of the present disclosure. Any modification, equivalent replacement, and improvement made within the spirit and principle of the present disclosure shall all fall within the protection scope of the present disclosure.

What is claimed is:

1. An active optical antenna, comprising:
a substrate;
a ground disposed at the bottom of the substrate;
a power supply grid and a plurality of antenna units that are disposed at the top of the substrate, and photodetector tubes that are disposed in the substrate and located between the antenna units and the ground, wherein the power supply grid supplies power to the photodetector tubes, the number of the photodetector tubes is equal to the number of the antenna units, and output ends of the photodetector tubes are coupled with the antenna units to output radio frequency signals; and
optical waveguides which are disposed in the substrate and connected to the photodetector tubes.

2. The active optical antenna according to claim 1, wherein the plurality of antenna units are arranged in an array, and the power supply grid is distributed in intervals between the antenna units.

3. The active optical antenna according to claim 1, wherein the substrate is any semiconductive material that is suitable for making an optical device and meets a requirement of a dielectric constant of an antenna substrate.

4. A microwave transmitting system, comprising:
a central office, configured to generate optical difference frequency signals to be transmitted, adjust the optical difference frequency signals to make them on an optical carrier, and transmit the signals to an active optical antenna through an optical fiber; and
the active optical antenna, configured to: through optical waveguides in a substrate of the active optical antenna, distribute optical signals received through the optical fiber to multiple photodetector tubes, wherein the multiple photodetector tubes convert the received optical difference frequency signals to radio frequency signals, and the radio frequency signals are sent out through antenna units.

5. The microwave transmitting system according to claim 4, wherein after generating the optical difference frequency signals to be transmitted, the central office is further configured to perform phase adjustment and control on the optical difference frequency signals, so as to adjust a phase of the optical carrier that arrives at each photodetector tube in the active optical antenna, and then adjust the optical difference frequency signals that have undergone the adjustment and control to make them on the optical carrier.

6. The microwave transmitting system according to claim 4, wherein the active optical antenna is located at a remote end of the central office.

7. A communication method, comprising:
powering on an active optical antenna;
receiving optical signals to be transmitted, and distributing the optical signals to multiple photodetector tubes through optical waveguides in a substrate of the active optical antenna; and
converting, by the multiple photodetector tubes, the received optical signals to radio frequency signals, and sending out the radio frequency signals through antenna units.

8. The method according to claim 7, wherein the received optical signals to be transmitted may have not undergone phase adjustment and control, or may have undergone phase adjustment and control.

9. The method according to claim 7, wherein the antenna units are arranged in an array.

10. The method according to claim 7, wherein the substrate is any semiconductive material that is suitable for making an optical device and meets a requirement of a dielectric constant of an antenna substrate.
